(19) United States
(12) Patent Application Publication
(10) Pub. No.: US 2010/0171201 A1
(43) Pub. Date: Jul. 8, 2010

(54) CHIP ON LEAD WITH SMALL POWER PAD DESIGN

(76) Inventors: M. Todd Wyant, Murphy, TX (US); Jeffrey G. Holloway, Plano, TX (US); Anthony L. Coyle, Parker, TX (US)

Correspondence Address: TEXAS INSTRUMENTS INCORPORATED, P O BOX 655474, M/S 3999, DALLAS, TX, 75265, US

(21) Appl. No.: 12/349,197

(22) Filed: Jan. 6, 2009

(51) Int. Cl. H01L 23/52; H01R 43/00

(52) U.S. Cl. 257/676; 29/592.1; 257/E23.141

(57) ABSTRACT

Embodiments of a semiconductor device and method provide a quad flat no-lead semiconductor package which can have an arrangement of both chip-on-lead (COL) style leads and a die pad for supporting a die, and can also provide non-COL leads, both COL leads and a leadframe power pad, COL leads which have varying lengths to reduce stress resulting from thermal mismatch between a semiconductor die and leads, and a die pad with a curved, meandering edge to reduce stress resulting from thermal mismatch between the semiconductor die and the die pad.

### FIELD OF THE INVENTION

This invention relates to the field of semiconductor device manufacture, and more particularly to semiconductor devices packaged as quad flat no-lead (QFN) devices.

### BACKGROUND OF THE INVENTION

A semiconductor device such as memory device, logic device, microprocessor, etc. is formed with conductive external connections to facilitate electrical coupling with test equipment, and eventual connection with a substrate such as a printed circuit board (PCB). Through-hole packages having leads which project through a printed circuit board, such as single in-line packages (SIPs) and dual in-line packages (DIPs), progressed to surface mount leads such as “j” style leads, which in turn progressed to surface mount connections such as flip chip and ball grid array (BGA) devices.

Semiconductor device package styles include various types of leadframes to which the die is attached. Leadframe designs can comprise a die paddle which can have a length and width which is smaller or larger than the die, or the same size as the die. A noncircuit (back) side of the die is adhered to the die paddle using a die attach material such as a liquid adhesive, double-sided tape, thermoplastic, or thermoset. Another type of leadframe is referred to as a “lead-on-chip” (LOC) leadframe. An LOC leadframe comprises no die paddle, but instead includes leads of an extended length which overlie the circuit (front) side of the die, and are adjacent to bond pads located toward a midline on the circuit side of the die. The LOC leads are attached to the die using a die attach material, then bond wires connect the bond pads with the leadframe leads. A “chip-on-lead” (COL) leadframe also comprises no die paddle, and includes leads of an extended length which project under the back side of the die to support the chip. Bond wires are connected to bond pads around the perimeter of the circuit side of the die and to the leads of the leadframe. The leads can be formed to provide a “downset” such that the bond pads on the front of the die are more even with the bond areas of the leadframe. After electrically coupling the bond pads with the leads, the die and internal leads of the device can be encapsulated or otherwise packaged.

Another type of surface mount package is known as a quad flat no-lead (QFN) device. This package style comprises the following elements: a stamped or etched electrically conductive leadframe having a die paddle and leads adjacent to, and spaced from, the die paddle; a semiconductor die having bond pads around a perimeter of the die; die attach material which adheres the back side of the die to the die paddle; conductive bond wires which electrically couple the bond pads on the die with the leads of the leadframe; and encapsulation material or other packaging which protects the die and the bond wires to minimize damage resulting from physical contact and from moisture and other contamination. To support the die and to assist with the dissipation of heat away from the die during device operation, the leadframe die paddle is typically the same size and shape as the die or larger to function as a heat sink subsequent to the attachment of the die. After completion of device packaging, the lower surface of the leadframe, including the die paddle and the external leads, are even with the encapsulation material and are therefore exposed. In addition to providing a heat sink to dissipate heat from the operating die, the die paddle can provide a “power pad” which can function as a path to ground for the semiconductor die using a conductive die attach material.

Regardless of the type of surface mount package, the leads of the device are attached to exposed, conductive contacts on the surface of the PCB using a thermally and electrically conductive material such as tin-lead solder. The conductive contacts on the PCB are electrically coupled with conductive traces which are routed away from the device. With the QFN package, the large, exposed surface of the die paddle is connected to a metal feature on the PCB which has approximately the same width and length as the exposed surface of the die paddle, for example using the tin-lead solder. Contact between the die paddle and the metal feature of the PCB draws heat away from the die.

### SUMMARY OF THE EMBODIMENTS

In contemplating semiconductor devices, the Applicants have realized several deficiencies of current package designs.

For example, while the size of the die paddle on a QFN lead frame efficiently draws heat away from the semiconductor die during device operation, it requires a large area of the PCB. This region of the PCB is a void for trace formation such that no traces can extend into this area. With device miniaturization, maximizing available “real estate” on the PCB is a goal of design engineers.

The Applicants have also realized that the current design of leadframes can be improved upon to allow packaging of a larger sized die and an increased number of package leads while maintaining outside package dimensions and providing a device having the advantages of a power pad.

Additionally, with leadframes having a chip-on-lead (COL) design, the leads which extend under the die are all the same length. The Applicants have realized that during device operation, thermal mismatch between the silicon die and the metal leadframe, combined with the uniform length of the leads and their attachment to the die, can create a line of high stress which can crack the die and lead to device failure. This risk of cracking is exacerbated when the crystal orientation of the chip (for example <100> or <110>) aligns with the line of stress imparted to the chip by the thermal mismatch of the leads and die during device operation. Even if the device does not fail, the stress can alter the electrical performance of the device during operation.

The Applicants have further realized that in devices having a square or rectangular die paddle, the thermal mismatch between the die and the metal leadframe can stress the die in much the same manner as discussed in the previous paragraph with reference to the uniform lead lengths. Using leadframes having a die paddle smaller than the die, this stress can be particularly high along the outside perimeter of the die paddle where the boundary of the paddle coincides with the crystal orientation of the chip's primary planes.

Additionally, the Applicants have realized that previous device designs incorporating a COL leadframe have been excluded from the advantages offered by a power pad, as previous designs of COL leadframes have not been compatible with a power pad feature.

After realizing these disadvantages of prior devices, the Applicants have developed a new semiconductor design, various embodiments of which comprise one or more design elements.

For example, at least a portion of the leadframe leads extend under the semiconductor die to provide a COL device, but the leads can be of unequal lengths to provide a staggered lead design. The staggered lead design more evenly distributes stresses which can result from thermal mismatch between the leadframe and the semiconductor die.

Additionally, the die paddle can be formed to have a rounded, meandering edge which more evenly distributes stresses across a larger area of the die.

Also, the leadframe can be formed to have two thicknesses, with outer portions of the leads and the die paddle being thicker than the inner portions of the leads located adjacent to the die paddle. This allows for a smaller power pad such that PCB traces can be routed under the die between the power pad and exposed leadframe leads.

Further, the leadframe design can also provide a device having a power pad, while still allowing for a larger die to be used while maintaining a particular device “footprint.”

The technical advances represented by the Applicants' device design, as well as the aspects thereof, will become apparent from the following description of the preferred embodiments of the invention, when considered in conjunction with the accompanying drawings and the novel features set forth in the appended claims.

### BRIEF DESCRIPTION OF THE DRAWINGS

The accompanying drawings, which are incorporated in and constitute a part of this specification, illustrate embodiments of the invention and together with the description, serve to explain the principles of the invention. In the figures:

FIG. 1 is a plan view of an embodiment of the invention;

FIG. 2 is a cross section along 2-2 of FIG. 1;

FIG. 3 is a cross section along 3-3 of FIG. 1;

FIG. 4 is a cross section along 4-4 of FIG. 1; and

FIG. 5 is an isometric depiction of an embodiment of the invention.

It should be noted that some details of the FIGS. have been simplified and are drawn to facilitate understanding of the inventive embodiments rather than to maintain strict structural accuracy, detail, and scale.

### DESCRIPTION OF THE EMBODIMENTS

Reference will now be made in detail to the present embodiments (exemplary embodiments) of the invention, an examples of which are illustrated in the accompanying drawings. Wherever possible, the same reference numbers will be used throughout the drawings to refer to the same or like parts.

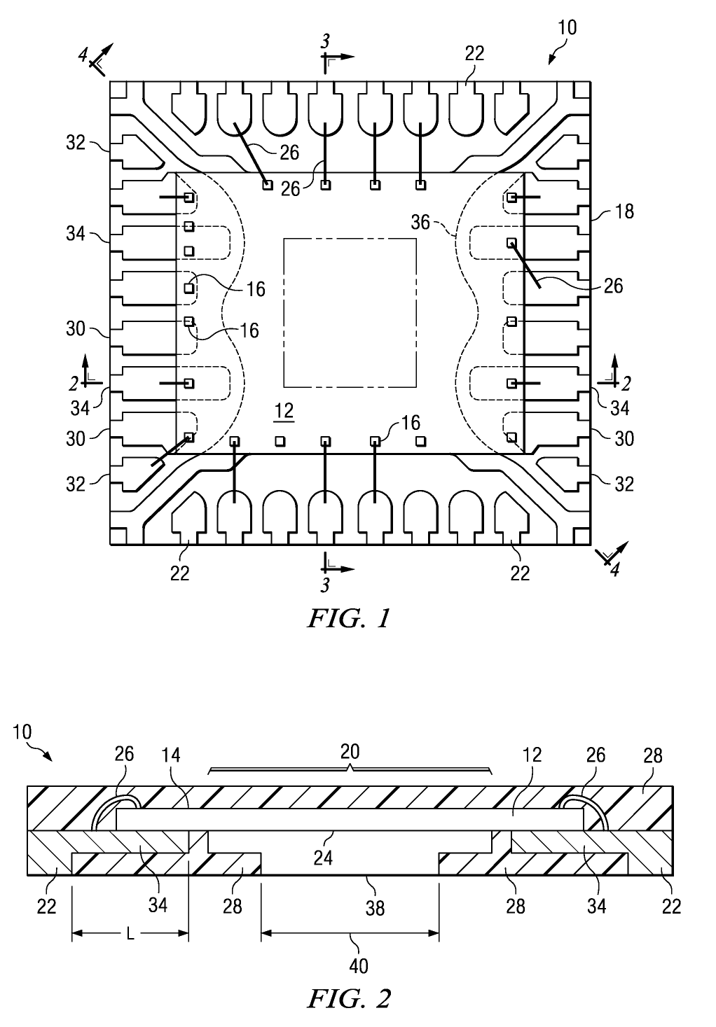

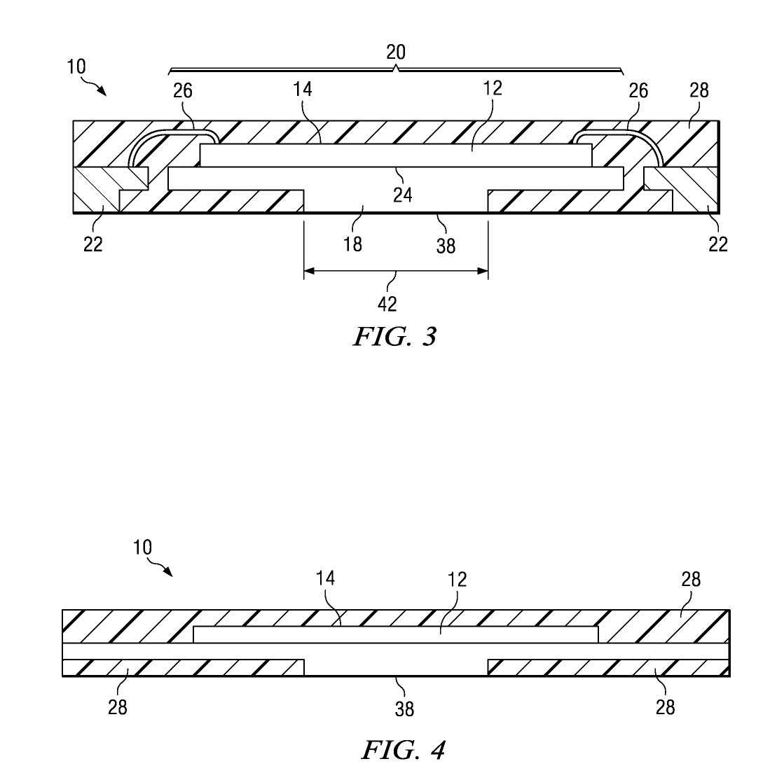

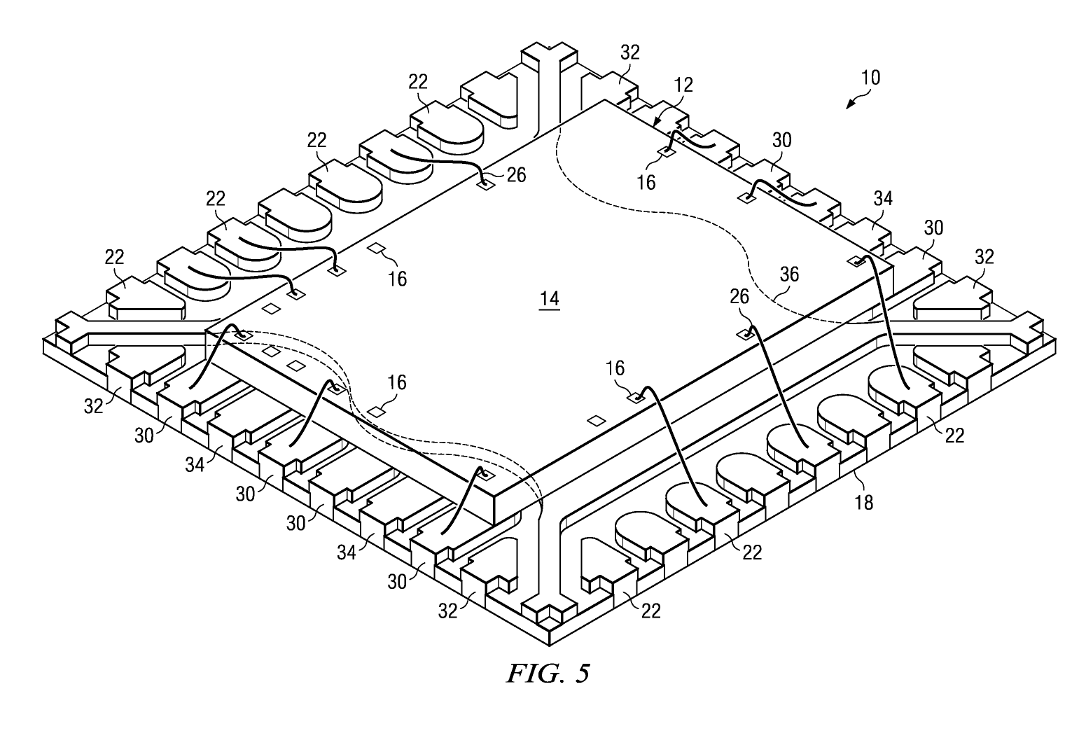

FIGS. 1-5 depict an embodiment of the present invention, which comprises a quad flat no-lead semiconductor device package. In the present illustrated embodiment, FIG. 1 is a plan view, FIG. 2 is a cross section along 2-2 of FIG. 1, FIG. 3 is a cross section along 3-3 of FIG. 1, FIG. 4 is a cross section along 4-4 of FIG. 1, and FIG. 5 is an isometric depiction. FIGS. 1-5 depict a QFN semiconductor device 10 comprising a semiconductor wafer section 12, which in the present embodiment is a single semiconductor die. It is contemplated, however, that the wafer section could also comprise a plurality of singularized semiconductor dice, for example stacked, singularized dice, or two or more unsingularized semiconductor dice. The semiconductor die further comprises a circuit (front) side 14 comprising circuitry (not depicted) and bond pads 16 thereon in accordance with conventional devices.

Further depicted is a semiconductor leadframe 18 comprising a die pad (paddle) 20 and a plurality of leads 22. A back side 24 of the die 12 is attached to the leadframe 18 using an adhesive (not depicted) such as a double-sided tape, a thermoplastic, a thermoset, etc. At least some, or all, of the bond pads 16 are electrically coupled to one or more leads 22 of the leadframe 18, for example using bond wires 26. Further depicted is an encapsulation material 28 which seals the die 12, the bond wires 26, and a portion of the leadframe 18 to prevent damage to the circuitry of the device which may result from physical contact during manufacture or use, from moisture or other contamination, etc.

A device formed in accordance with the present teachings can comprise one or more of various features as described below.

As depicted in FIG. 1, a plurality of leads along the left side and the plurality of leads along the right side are staggered. In this disclosure, “staggered” leads refers to a plurality of leads which comprise leads having varying length and which extend under the semiconductor die. In a particular embodiment, no more than two adjacent leads have the same length, and the leads within the plurality have at least two different lengths. In another embodiment, no more than three adjacent leads have the same length, and the leads within the plurality have at least two different lengths, or at least three different lengths. FIG. 1 depicts first leads 30 having a first length, second leads 32 having a second length which shorter than the first length, and third leads 34 having a third length which is longer than the first and second lengths. In this embodiment, the second leads 32 do not extend under the semiconductor device. and therefore are not COL leads and are not part of the “staggered” leads. The length is designated as “L” in FIG. 2 and is measured from the end of the lead proximate to the die to the beginning of the thicker portion which will be exposed on the outer surface of the packaging. Leadframes having staggered leads of two lengths as depicted, or more than two lengths, are also contemplated. Additionally, in the FIG. 1 embodiment, only the first plurality of leads depicted on the left and right sides of the FIG. are staggered, but an embodiment can also be formed which comprises staggered leads along three or four sides of the frame.

In this embodiment as depicted in FIGS. 1 and 2, the left and right edges of the die 12 extend over the leads to provide a partial chip-on-lead (COL) style leadframe on “COL leadframe sides” of the device. The semiconductor die 12 is attached to the die pad 20 and the leads 22 on the left and right sides of the FIGS. with a die attach material. In a conventional COL packages, each lead has the same or similar length. The inventors have realized that thermal mismatch between the die and the leadframe can stress and crack the die, particularly toward the ends of the leads. With conventional leads having the same length, the stress is imparted to the die along a single line. Problems resulting from stress are exacerbated when the crystal orientation of the chip (for example <100> or <110>) aligns with the line of stress imparted to the chip by the thermal mismatch of the leads and die during device operation. Even if the device does not fail, the stress can alter the electrical performance of the device during operation. With staggered leads, the stress is more evenly distributed across the back surface of the die, for example across multiple interstitial lines of the chip. Thus with staggered leads, maximum stress to a given point on the die can be reduced.

As further depicted in FIG. 1, the die pad 20 at the left and right COL leadframe sides, comprises curved, meandering edges 36. In this disclosure, a “meandering” edge is one which has a variable, changing slope along its length. A conventional device comprising COL leads does not comprise a die pad. However, in other types of devices which do comprise a die pad, the edges are typically straight. The inventors have realized that supporting a die which hangs over a straight leadframe die pad edge, in combination with a thermal mismatch between the die and lead frame, can stress the die in much the same manner as the nonstaggered leads described above. Thus the curved, meandering die pad edges 36 as depicted in FIG. 1 more evenly distributes the stresses across the surface of the die, resulting in reduction of stress for a given point on the surface of the die as compared to nonstaggered leads.

This embodiment of the device also comprises a second plurality of leads on two sides of the die, wherein the leads are not attached to the back side of the die, and the die does not overlie the second plurality of leads. Thus these leads do not provide a COL arrangement of die and leads, and thus provide “non-COL” leads. In FIG. 1, the upper and lower rows of leads abut the edge of the die, but do not underlie the die. This is reflected in FIG. 3, which is a cross section along 3-3 of FIG. 1 in which non-COL leads are depicted at the left and right sides of the FIG., and provide “non-COL sides” of the leadframe. In contrast to the COL leads depicted, the plurality non-COL leads are generally the same length, and more than three adjacent leads are the same length. In various embodiments, the maximum number of adjacent non-COL leads having the same length will be greater than the maximum number of adjacent COL leads having the same length.

Thus in a first cross section in a first direction (in FIG. 1, left to right) which encompasses the die, the die pad, and leadframe leads, the die is supported by both the leadframe leads and a die pad. In a second cross section in a second direction perpendicular with the first direction. (in FIG. 1, top to bottom) which encompasses the die, the die pad, and leadframe leads, the die is supported by the die pad but is not supported by leadframe leads.

The leadframe 18 of device package 10 depicted in FIGS. 1-4 further comprises a power pad 38. The power pad, as depicted in the FIG. 2 cross section along 2-2 of FIG. 1, has a width 40 and, as depicted in the FIG. 3 cross section along 3-3 of FIG. 1, a length 42. The power pad, which can be square, rectangular, or another shape, is provided by stamping or etching through a thickness of the leadframe to provide a thicker portion which forms the power pad and a thinner portion which provides a die pad. An advantage of the power pad in this embodiment is that the power pad can be provided in a partial COL package. Previously, a power pad was not compatible with a COL-style leadframe. Further, if the device comprises COL leadframe sides on all four sides of the device, the device can be formed with a full COL package and also comprise a power pad. An advantage of a power pad is that it provides a heat sink for the operational die, and can also be used to provide a ground connection for the die. Previously, a COL package leadframe has not been compatible with a power pad.

In the present embodiment, the power pad is formed of a reduced size such that traces on a printed circuit board (PCB) to which it is later attached can be routed under the packaged chip between the exposed leads and the exposed power pad. With previous QFN package designs, the area on the PCB within the large perimeter of the packaged QFN device is a void for trace formation. While the traces are electrically insulated, for example with a layer of phenolic resin, an operating semiconductor device can electrically interfere with signals on the electrical traces which are in close proximity (under) the semiconductor device. Also, the PCB can comprise an exposed metal pad on the board that roughly matches the power pad in size so as to allow for an optimum solder connection, but which prevents the formation of PCB traces under the entire area of the encapsulated package. Forming a power pad of reduced dimensions allows additional spacing between the leads and the power pad to route traces. Providing additional space for trace formation at a location under the encapsulated device gives a design engineer additional room on the PCB to route traces between contact pads on the board.

The present leadframe design also allows the size of the die to be increased while maintaining outside package dimensions, while also providing a device with a power pad. For example, the size of the die can be increased along the axis of the COL leads, as long as the resulting packaging material 28 does not become excessively thin at the edges of the die. Thus this advantage of a COL leadframe device is available in a package which can also comprise a power pad.

As depicted in FIGS. 1-5, the first plurality of COL leads (left and right sides of FIGS. 1 and 2) and the second plurality of non-COL leads (upper and lower sides of FIG. 1, and left and right sides of FIG. 2) each have a top surface and a bottom surface. With the COL leads, a plane of the top surface is generally aligned with a surface of the die pad which is attached to the back of the semiconductor die. Additionally, ends of the COL leads, in a staggered arrangement, provide a curved, meandering contour. A contour of the curved, meandering edge of the die pad proximate to the COL leads follows the contour of the ends of the COL leads. In the embodiment depicted, the die pad also comprises a straight edge which is proximate the non-COL leads, and the non-COL leads are straight as they are generally the same length and provide a straight edge along their ends. In this embodiment, the top of the non-COL leads are also even with the upper surface of the die paddle, however comprising a downset paddle and non-COL leads having upper surfaces level with the front side of the die are also contemplated.

Thus embodiments of the present invention provide a QFN leadframe design with a reduced power pad which allows for under chip routing in narrow spaces when mounted on a circuit board where both power dissipation and die proximity to package node are tight. It also allows a larger die to be placed into a package node. The leadframe can be designed with a power pad which is sufficiently small to dissipate heat, but also leaves room between the leads and power pad for under-package routing on a circuit board application. This design also incorporates lead-over-chip design as well as an exposed power pad. The lead-on-chip design is staggered to reduce stress to the die from the lead tips and power pad.

Notwithstanding that the numerical ranges and parameters setting forth the broad scope of the invention are approximations, the numerical values set forth in the specific examples are reported as precisely as possible. Any numerical value, however, inherently contains certain errors necessarily resulting from the standard deviation found in their respective testing measurements. Moreover, all ranges disclosed herein are to be understood to encompass any and all sub-ranges subsumed therein. For example, a range of “less than 10” can include any and all sub-ranges between (and including) the minimum value of zero and the maximum value of 10, that is, any and all sub-ranges having a minimum value of equal to or greater than zero and a maximum value of equal to or less than 10, e.g., 1 to 5. In certain cases, the numerical values as stated for the parameter can take on negative values. In this case, the example value of range stated as “less that 10” can assume negative values, e.g. −1, −2, −3, −10, −20, −30, etc.

While the invention has been illustrated with respect to one or more implementations, alterations and/or modifications can be made to the illustrated examples without departing from the spirit and scope of the appended claims. In addition, while a particular feature of the invention may have been disclosed with respect to only one of several implementations, such feature may be combined with one or more other features of the other implementations as may be desired and advantageous for any given or particular function. Furthermore, to the extent that the terms “including,” “includes,” “having,” “has,” “with,” or variants thereof are used in either the detailed description and the claims, such terms are intended to be inclusive in a manner similar to the term “comprising.” The term “at least one of” is used to mean one or more of the listed items can be selected. Further, in the discussion and claims herein, the term “on” used with respect to two materials, one “on” the other, means at least some contact between the materials, while “over” means the materials are in proximity, but possibly with one or more additional intervening materials such that contact is possible but not required. Neither “on” nor “over” implies any directionality as used herein. The term “about” indicates that the value listed may be somewhat altered, as long as the alteration does not result in nonconformance of the process or structure to the illustrated embodiment. Finally, “exemplary” indicates the description is used as an example, rather than implying that it is an ideal. Other embodiments of the invention will be apparent to those skilled in the art from consideration of the specification and practice of the invention disclosed herein. It is intended that the specification and examples be considered as exemplary only, with a true scope and spirit of the invention being indicated by the following claims.

1. A semiconductor device, comprising:
a semiconductor wafer section comprising a front side having circuitry thereon and a back side; and
a leadframe comprising:
a die pad attached to the back side of the semiconductor wafer section;
a first plurality of leads along a first edge of the die pad attached to the back side of the semiconductor wafer section; and
a second plurality of leads along a second edge of the die pad wherein the second plurality of leads are not attached to the back side of the semiconductor wafer section.

2. The semiconductor device of claim 1 wherein the first plurality of leads comprises no more than three adjacent leads of the same length which are attached to the back side of the semiconductor wafer section and the leads in the first plurality of leads have at least two different lengths.

3. The semiconductor device of claim 2 wherein the second plurality of leads comprises three or more adjacent leads of the same length which are not attached to the back of the semiconductor wafer section.

4. The semiconductor device of claim 2, wherein:
ends of the first plurality of leads provide a contour; and
the die pad has an edge adjacent the first plurality of leads, wherein a contour of the die pad edge follows the contour of the ends of the first plurality of leads.

5. The semiconductor device of claim 1, wherein:
ends of the first plurality of leads provide a contour; and
the die pad has an edge having a contour which follows the contour of the ends of the first plurality of leads, wherein the die pad edge contour comprises a curved, meandering shape which follows the contour of the ends of the first plurality of leads.

6. The semiconductor device of claim 1, further comprising:
encapsulation material which encapsulates the die and a portion of the leadframe; and
a power pad on a surface of the die pad which is exposed on an outside surface of the encapsulation material.

7. A semiconductor device, comprising:
a semiconductor wafer section comprising a front side having circuitry thereon and a back side; and
a leadframe comprising:
a die pad attached to the back side of the semiconductor wafer section;
a power pad on a surface of the die pad, and
a plurality of leads along a first edge of the die pad, wherein the plurality of leads are attached to the back side of the semiconductor wafer section.

8. The semiconductor device of claim 7, wherein the plurality of leads is a first plurality of leads and the semiconductor device further comprises:
a second plurality of leads along a second edge of the die pad, wherein the second plurality of leads are not attached to the back side of the semiconductor wafer section.

9. The semiconductor device of claim 8, further comprising:
the first plurality of leads comprising a maximum number of adjacent leads having the same length; and
the second plurality of leads comprising a maximum number of adjacent leads having the same length,
wherein the maximum number of adjacent leads having the same length of the second plurality is greater than the maximum number of adjacent leads having the same length of the first plurality.

10. The semiconductor device of claim 8 wherein the die pad comprises a curved, meandering first edge adjacent the first plurality of leads and a straight second edge adjacent the second plurality of leads.

11. The semiconductor device of claim 8 further comprising an encapsulation material which encapsulates the die and a portion of the leadframe, wherein the power pad is exposed on an exterior of the encapsulation material.

12. A semiconductor device leadframe, comprising:
a die pad having a first edge and a second edge;
a power pad:
a first plurality of leads along the first edge of the die pad, wherein the first plurality of leads are staggered; and
a second plurality of leads along the second edge of the die pad, wherein the second plurality of leads are straight.

13. The semiconductor device leadframe of claim 12, further comprising:
the first plurality of leads having no more than three adjacent leads which have the same length; and
the second plurality of leads having more three adjacent leads which have the same length.

14. The leadframe of claim 13, wherein:
the first edge is a curved, meandering edge proximate to the first plurality of leads; and
the second edge is a straight edge proximate to the second plurality of leads.

15. A method of forming a semiconductor device, comprising:
attaching a back side of a semiconductor wafer section to a leadframe die pad using a die attach material; and
attaching a first plurality of leads along a first edge of the die pad to the back side of the semiconductor wafer section;
wherein, subsequent to attaching the first plurality of leads to the back side of the semiconductor wafer section, no lead along a second edge of the die pad is attached to the back side of the semiconductor wafer section.

16. The method of claim 15, further comprising:
attaching a first bond wire to a first bond pad on a front side of the semiconductor wafer section and to one of said first plurality of leads; and
attaching a second bond wire to a second bond pad on the front side of the semiconductor wafer section and to one of the second plurality of leads wherein, subsequent to attaching the second bond wire, no lead along the second edge of the die pad is attached to the back side of the semiconductor wafer section.

17. The semiconductor device of claim 16, further comprising encapsulating the semiconductor wafer section and a portion of the leadframe wherein, subsequent to encapsulation, a power pad formed by a surface of the leadframe is exposed on an outer surface of the encapsulation material.
